(19) United States
(12) Patent Application Publication
(10) Pub. No.: US 2021/0391404 A1
(43) Pub. Date: Dec. 16, 2021

(54) DISPLAY PANEL, MANUFACTURING METHOD THEREOF, AND DISPLAY DEVICE

(71) Applicant: WUHAN CHINA STAR OPTOELCTRONICS SEMICONDUCTOR DISPLAY TECHNOLOGY CO., LTD., Wuhan, Hubei (CN)

(72) Inventors: Jing ZHOU, Wuhan, Hubei (CN); Yixian ZHANG, Wuhan, Hubei (CN); Wenxu XIANYU, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/056,458

(22) PCT Filed: Jun. 23, 2020
(86) PCT No.: PCT/CN2020/097797

§ 371 Date: Nov. 18, 2020

(30) Foreign Application Priority Data
Jun. 11, 2020 (CN) 202010527205.0

(51) Int. Cl. H01L 27/32; H01L 51/56

(52) U.S. Cl. CPC H01L 27/3276; H01L 51/56; H01L 27/3246

(57) ABSTRACT

A display panel, a manufacturing method thereof, and a display device are provided. In the display panel, a conversion terminal layer is formed on a first substrate to form a conversion terminal, a first opening is formed at a position on the first substrate corresponding to the conversion terminal, and a data line formed from a source/drain layer is connected to the conversion terminal by a first through-hole. Therefore, when a driver chip is connected to the display panel, the driver chip can be connected to the data line of the source/drain layer by the conversion terminal layer.

### FIELD

The present disclosure relates to the field of display technologies, and more particularly, relates to a display panel, a manufacturing method thereof, and a display device.

### BACKGROUND

With development of display technologies, conventional display panels are designed to have high screen-to-body ratio, thereby obtaining full-screen panels. However, circuits and metal line areas are defined at outer frames of the display panels, resulting in relatively thick outer frames of the display panels. Moreover, outer frame areas cannot display, contributing to relatively low screen-to-body ratio. As shown in FIG. 1, a conventional display device 1 includes a display area 12 and a non-display area 11. The non-display area 11 includes a first power supply voltage line 111, a panel test line 112, a gate driving circuit 113, a second power supply voltage line 114, an electrostatic protection circuit 115, a first fan-out area 116, a third power supply voltage line 117, an array test line 118, a bending area 119, a second fan-out area 120, a driver chip 121, and a flexible circuit board 122. As demonstrated In FIG. 1, each line, each area, and each circuit are distributed around a display panel, and a width of the non-display area is greater due to a large number and greater widths of lines, leading to relatively large outer frames and relatively low screen-to-body ratio of the display device.

Regarding the technical problem: widths of outer frames of conventional display devices are greater due to many lines disposed at the outer frames, resulting in relatively low screen-to-body ratio of the display devices.

### SUMMARY

An embodiment of the present disclosure provides a display panel, a manufacturing method thereof, and a display device to alleviate a following technical problem: a width of outer frames of conventional display devices is large due to too many lines disposed at the outer frames, resulting in relatively low screen-to-body ratio of the display devices.

To solve the above problem, technical solutions provided by the present disclosure are described below.

An embodiment of the present disclosure provides a display panel, including:

a first substrate;

a conversion terminal layer disposed on the first substrate to form a conversion terminal;

a barrier layer disposed on the conversion terminal layer;

a buffer layer disposed on the barrier layer;

a driving circuit layer including an active layer, a first gate insulating layer, a first metal layer, a second gate insulating layer, a second metal layer, an interlayer insulating layer, and a source/drain layer, wherein the driving circuit layer is disposed on the buffer layer;

a planarization layer;

a pixel defining layer; and

a luminescent functional layer;

wherein a first opening is formed at a position on the first substrate corresponding to the conversion terminal, and a data line formed from the source/drain layer is connected to the conversion terminal by a first through-hole.

In some embodiments, a fan-out line is formed from the conversion terminal layer, an end of the fan-out line is connected to the conversion terminal, and another end of the fan-out line is connected to the data line of the source/drain layer by the first through-hole.

In some embodiments, a clock signal line is formed from the conversion terminal layer, an end of the clock signal line is connected to the conversion terminal, and another end of the clock signal line is connected to a gate driving circuit of the display panel.

In some embodiments, the first metal layer is etched to form a gate, and the clock signal line is connected to the gate by a second through-hole.

In some embodiments, an electrostatic protection circuit line is formed from the conversion terminal layer, an end of the electrostatic protection circuit line is connected to the conversion terminal, and another end of the electrostatic protection circuit line is connected to an electrostatic protection circuit of the display panel.

In some embodiments, a test terminal is formed from the conversion terminal layer, and a second opening is formed at a position on the first substrate corresponding to the test terminal.

In some embodiments, the barrier layer includes a first barrier layer, a second barrier layer, and a second substrate disposed between the first barrier layer and the second barrier layer, the first barrier layer is disposed on the first substrate, and the conversion terminal layer includes a first part disposed on the first substrate and a second part disposed on the second substrate.

In some embodiments, a material of the conversion terminal layer and a material of the source/drain layer are same.

Meanwhile, an embodiment of the present disclosure provides a method of manufacturing a display panel, including following steps:

providing a first substrate;

forming a conversion terminal layer on the first substrate, and etching the conversion terminal layer to form a conversion terminal;

forming a barrier layer on the conversion terminal layer;

forming a buffer layer on the barrier layer;

forming an active layer, a first gate insulating layer, a first metal layer, a second gate insulating layer, a second metal layer, and an interlayer insulating layer on the buffer layer, performing an exposure process to form an exposed hole, and etching the exposed hole to obtain a first through-hole;

forming a source/drain layer on the interlayer insulating layer to obtain a driving circuit layer, wherein the source/drain layer is connected to the conversion terminal by the first through-hole; and

forming a planarization layer, a pixel defining layer, and a luminescent functional layer on the source/drain layer to obtain the display panel.

Meanwhile, an embodiment of the present disclosure provides a display device, including:

a display panel including a first substrate, a conversion terminal layer, a barrier layer, a buffer layer, a driving circuit layer, a planarization layer, a pixel defining layer, a luminescent functional layer, wherein the conversion terminal layer is disposed on the first substrate to form a conversion terminal, the barrier layer is disposed on the conversion terminal layer, the buffer layer is disposed on the barrier layer, the driving circuit layer includes an active layer, a first gate insulating layer, a first metal layer, a second gate insulating layer, a second metal layer, an interlayer insulating layer, and a source/drain layer, and the driving circuit layer is disposed on the buffer layer. A first opening is formed at a position on the first substrate corresponding to the conversion terminal, and a data line formed from the source/drain layer is connected to the conversion terminal by a first through-hole;

the display device further includes: an auxiliary functional layer disposed under the display panel; and

a driver chip disposed under the display panel and connected to the conversion terminal.

In some embodiments, a third opening is formed on the auxiliary functional layer, and the driver chip is connected to the conversion terminal by the third opening.

In some embodiments, the auxiliary functional layer includes a support layer, a heat dissipation layer, and a backplate.

In some embodiments, a fan-out line is formed from the conversion terminal layer, an end of the fan-out line is connected to the conversion terminal, and another end of the fan-out line is connected to the data line of the source/drain layer by the first through-hole.

In some embodiments, a clock signal line is formed from the conversion terminal layer, an end of the clock signal line is connected to the conversion terminal, and another end of the clock signal line is connected to a gate driving circuit of the display panel.

In some embodiments, the first metal layer is etched to form a gate, and the clock signal line is connected to the gate by a second through-hole.

In some embodiments, an electrostatic protection circuit line is formed from the conversion terminal layer, an end of the electrostatic protection circuit line is connected to the conversion terminal, and another end of the electrostatic protection circuit line is connected to an electrostatic protection circuit of the display panel.

In some embodiments, a test terminal is formed from the conversion terminal layer, and a second opening is formed at a position on the first substrate corresponding to the test terminal.

In some embodiments, the barrier layer includes a first barrier layer, a second barrier layer, and a second substrate disposed between the first barrier layer and the second barrier layer, the first barrier layer is disposed on the first substrate, and the conversion terminal layer includes a first part disposed on the first substrate and a second part disposed on the second substrate.

In some embodiments, a material of the conversion terminal layer and a material of the source/drain layer are same.

In some embodiments, the material of the conversion terminal layer includes at least one of Ti, Al, or Cu.

Regarding the beneficial effects: the present disclosure provides a display panel, a manufacturing method thereof, and a display device. The display panel includes a first substrate, a conversion terminal layer, a barrier layer, a buffer layer, a driving circuit layer, a planarization layer, a pixel defining layer, and a luminescent functional layer. The conversion terminal layer is disposed on the first substrate to form a conversion terminal. The barrier layer is disposed on the conversion terminal layer. The buffer layer is disposed on the barrier layer. The driving circuit layer includes an active layer, a first gate insulating layer, a first metal layer, a second gate insulating layer, a second metal layer, an interlayer insulating layer, and a source/drain layer. The driving circuit layer is disposed on the buffer layer. Wherein, a first opening is formed at a position on the first substrate corresponding to the conversion terminal, and a data line formed from the source/drain layer is connected to the conversion terminal by a first through-hole. In the present disclosure, by forming the conversion terminal layer on the first substrate to form the conversion terminal and forming the first opening at the position on the first substrate corresponding to the conversion terminal, a data line formed from the source/drain layer can be connected to the conversion terminal by the first through-hole, and a driver chip can be connected to the data line of the source/drain layer by the conversion terminal layer. Therefore, the driver chip can be connected to the display panel without defining a fan-out area, a binding terminal, and a bending area at a bottom outer frame of the display panel, which reduces a width of outer frames and increases a screen-to-body ratio of the display panel. As a result, a following technical problem can be alleviated: widths of outer frames of conventional display devices are greater due to many lines disposed at the outer frames, resulting in relatively low screen-to-body ratio of the display devices.

### DESCRIPTION OF DRAWINGS

FIG. 1 is a schematic view showing a conventional display panel.

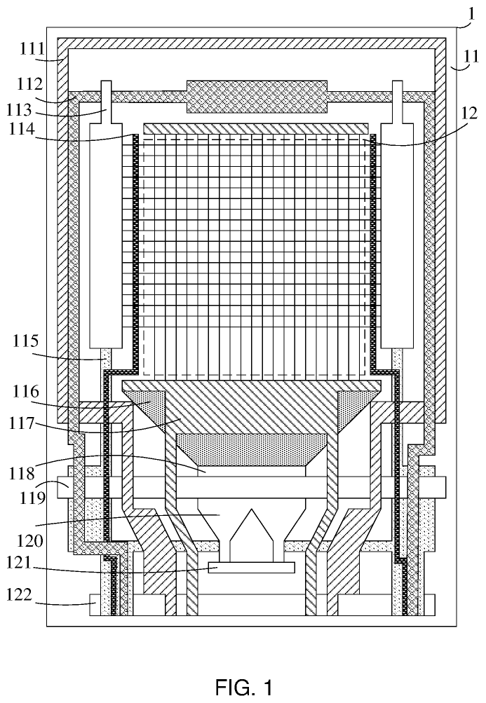

FIG. 2 is a first schematic view showing a display panel provided by an embodiment of the present disclosure.

FIG. 3 is a second schematic view showing the display panel provided by an embodiment of the present disclosure.

FIG. 4 is a schematic view showing an arrangement of lines of a conversion terminal layer provided by an embodiment of the present disclosure.

FIG. 5 is a schematic view showing a position on the conventional display panel where a through-hole is defined according to an embodiment of the present disclosure.

FIG. 6 is a schematic view showing a position on a conventional circuit disposing area where the through-hole is defined according to the embodiment of the present disclosure

FIG. 7 is a flowchart showing a method of manufacturing a display panel according to an embodiment of the present disclosure.

FIG. 8 is a schematic view showing a display device provided by an embodiment of the present disclosure.

### DETAILED DESCRIPTION

The present disclosure provides a display panel, a manufacturing method thereof, and a display device. Embodiments are further described below in detail with reference to accompanying drawings to make objectives, technical solutions, and effects of the present disclosure clearer and more precise. It should be noted that described embodiments are merely used to construct the present disclosure and are not intended to limit the present disclosure.

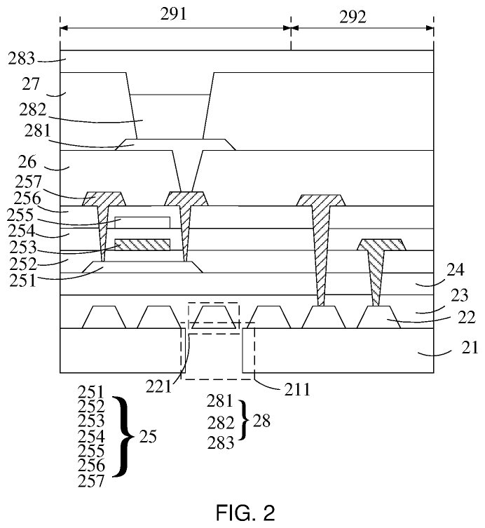

As shown in FIG. 2, an embodiment of the present disclosure provides a display panel, including:

a first substrate 21;

a conversion terminal layer 22 disposed on the first substrate 21 to form a plurality of conversion terminals 221;

a barrier layer 23 disposed on the conversion terminal layer 22;

a buffer layer 24 disposed on the barrier layer 23;

a driving circuit layer 25 including an active layer 251, a first gate insulating layer 252, a first metal layer 253, a second gate insulating layer 254, a second metal layer 255, an interlayer insulating layer 256, and a source/drain layer 257, wherein the driving circuit layer 25 is disposed on the buffer layer 24;

a planarization layer 26;

a pixel defining layer 27; and

a luminescent functional layer 28.

Wherein, a first opening 211 is formed at a position on the first substrate 21 corresponding to the conversion terminal 221, and a data line formed from the source/drain layer 257 is connected to the conversion terminal 221 by a first through-hole.

The present disclosure provides a display panel, a manufacturing method thereof, and a display device. The display panel includes a first substrate, a conversion terminal layer, a barrier layer, a buffer layer, a driving circuit layer, a planarization layer, a pixel defining layer, and a luminescent functional layer. The conversion terminal layer is disposed on the first substrate to form a conversion terminal. The barrier layer is disposed on the conversion terminal layer. The buffer layer is disposed on the barrier layer. The driving circuit layer includes an active layer, a first gate insulating layer, a first metal layer, a second gate insulating layer, a second metal layer, an interlayer insulating layer, and a source/drain layer. The driving circuit layer is disposed on the buffer layer. Wherein, a first opening is formed at a position on the first substrate corresponding to the conversion terminal, and a data line formed from the source/drain layer is connected to the conversion terminal by a first through-hole. In the present disclosure, by forming the conversion terminal layer on the first substrate to form the conversion terminal and forming the first opening at the position on the first substrate corresponding to the conversion terminal, a data line formed from the source/drain layer can be connected to the conversion terminal by the first through-hole, and a driver chip can be connected to the data line of the source/drain layer by the conversion terminal layer. Therefore, the driver chip can be connected to the display panel without defining a fan-out area, a binding terminal, and a bending area at a bottom outer frame of the display panel, which reduces a width of outer frames and increases screen-to-body ratio of the display panel. As a result, a following technical problem can be alleviated: widths of outer frames of conventional display devices are greater due to many lines disposed at the outer frames, resulting in relatively low screen-to-body ratio of the display devices.

It should be noted that FIG. 2 neither shows the data line nor the first through-hole blocked by the source/drain layer.

In one embodiment, the luminescent functional layer 28 includes a pixel electrode layer 281, a luminescent material layer 282, and a common electrode layer 283. A material of the pixel electrode layer includes indium tin oxide (ITO), the luminescent material layer is disposed on a pixel area defined by the pixel defining layer, and a material of the common electrode layer includes ITO.

In one embodiment, as shown in FIG. 2, the display panel includes a display area 291 and a hole defining area 292. The through-hole configured to connect a metal line of the source/drain layer and a metal line the gate layer to the conversion terminal layer can be formed in the hole defining area, thereby preventing circuits in the display area from being affected by the through-hole.

In one embodiment, the hole defining area is defined around the display area, thereby allowing lines at outer frames of conventional display devices to be disposed on the conversion terminal layer, and to be connected to a driving circuit of the display area by the through hole. Therefore, each circuit of the display panel can work normally, a width of outer frames of the display panel can be reduced, and a screen-to-body ratio of the display panel can be increased.

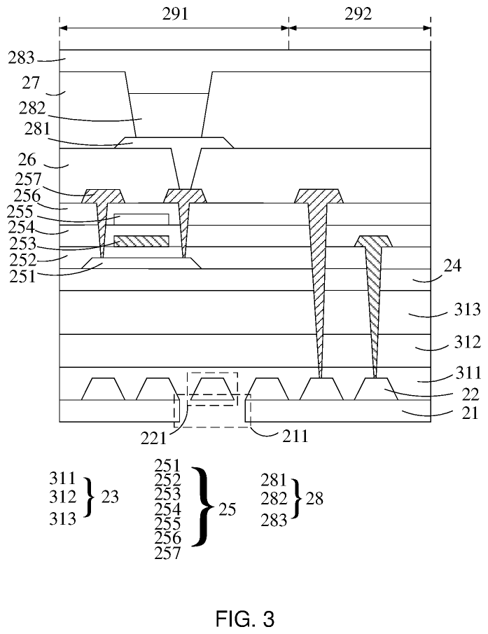

In one embodiment, as shown in FIG. 3, the barrier layer 23 includes a first barrier layer 311, a second barrier layer 313, and a second substrate 312 disposed between the first barrier layer 311 and the second barrier layer 313. The first barrier layer 311 is disposed on the first substrate 21. The conversion terminal layer includes a first part disposed on the first substrate and a second part disposed on the second substrate. In display panels including the first barrier layer, the second substrate, and the second barrier layer, the first part of the conversion terminal layer is formed on the first substrate to form the conversion terminal, and the second part of the conversion terminal layer is formed on the second substrate to form a plurality of lines. The conversion terminal is disposed on the first substrate, so that the driver chip can be connected to the display panel without forming an opening on multiple layers. In addition, in the present embodiment, an opening has a relatively shallow depth, so that it will not affect capability of the block barrier to prevent erosion due to moisture and oxygen. In addition, when a metal line of a first metal layer and a metal line of the source/drain layer are directly connected to the conversion terminal layer, a height of the metal line of the first metal layer, the metal line of the source/drain layer, or the terminal may be relatively low. Therefore, the second part of the conversion terminal layer is disposed on the second substrate to reduce possibility of breakage of the metal line of the first metal layer, the metal line of the source/drain layer, or the terminal.

In one embodiment, when an opening is formed at a bottom side of the first substrate, the opening can be encapsulated after the driver chip is already disposed in the display device, thereby preventing erosion of the conversion terminal layer and the driver chip due to moisture and oxygen. Conventional procedures and processes used to encapsulate a hole and an opening can be applied, but an encapsulating method of the present disclosure is not limited thereto, any method to prevent moisture and oxygen from entering the display device can be applied.

In one embodiment, the conversion terminal is disposed in the hole defining area, thereby directly connecting the data line to the conversion terminal by the through-hole.

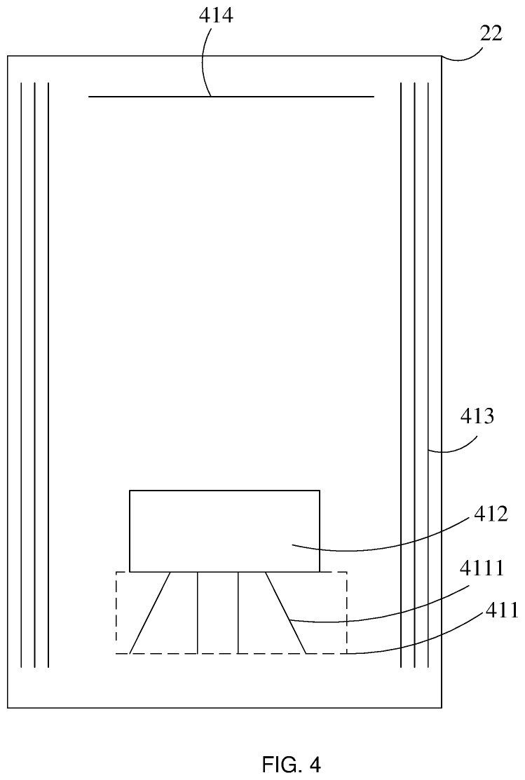

In one embodiment, a fan-out line is formed from the conversion terminal layer, an end of the fan-out line is connected to the conversion terminal, and another end of the fan-out line is connected to the data line of the source/drain layer by the first through-hole. Specifically, as shown in FIG. 4, a fan-out area 411 and a driver chip binding area 412 are defined at a bottom side of the conversion terminal layer 22. A fan-out line 4111 is disposed in the fan-out area 411. The conversion terminal is disposed in the driver chip binding area 12. The fan-out line may be formed from the conversion terminal layer when the conversion terminal is connected to the data line. After that, the data line is connected to the fan-out line by the first through-hole, and then the fan-out line is also connected to the conversion terminal, thereby connecting the data line to the fan-out line. By doing so, the data line can be connected to the driver chip even if the driver chip is disposed in the display area. Correspondingly, arrangements of other lines and terminals may also be determined according to requirements, so that terminals and lines of the conversion terminal layer can be regularly arranged, and space in the conversion terminal layer can be fully utilized. By disposing lines, which are originally disposed around conventional display devices, on the conversion terminal layer, the width of outer frames of the display panel can be reduced, and the screen-to-body ratio of the display panel can be increased.

In one embodiment, a clock signal line is formed from the conversion terminal layer, an end of the clock signal line is connected to the conversion terminal, and another end of the clock signal line is connected to a gate driving circuit of the display panel. Specifically, as shown in FIG. 4, a plurality of clock signal lines 413 are formed at two sides of the conversion terminal layer 22, so that the clock signal lines are formed in the display area and a through-hole area of the display panel, and there is no need to form the clock signal lines at the outer frames of the display panel. Therefore, the width of the outer frames of the display panel is reduce, and the screen-to-body ratio of the display panel is increased.

In one embodiment, the first metal layer is etched to form a gate, and the clock signal line is connected to the gate by a second through-hole. When the clock signal line is connected to the gate driving circuit, the gate can be connected to the clock signal line of the conversion terminal layer by the through-hole, thereby allowing the clock signal line to provide signals for the gate driving circuit.

In one embodiment, an electrostatic protection circuit line is formed from the conversion terminal layer, an end of the electrostatic protection circuit line is connected to the conversion terminal, and another end of the electrostatic protection circuit line is connected to an electrostatic protection circuit of the display panel. In the display panel, the electrostatic protection circuit line is disposed on the conversion terminal layer. Correspondingly, the conversion terminal layer may also be provided with a through-hole and a connecting wire, so that the electrostatic protection circuit can be connected to the electrostatic protection circuit line, and an electrostatic protection function can be realized. Furthermore, the width of the outer frames of the display panel can be reduced, and the screen-to-body ratio of the display panel can be increased.

In one embodiment, a power supply voltage line is formed from the conversion terminal line. Specifically, as shown in FIG. 4, a power supply voltage line 414 is formed from the conversion terminal layer 22. Compared with conventional technologies (the power supply voltage line is disposed at outer frames of display devices), the present embodiment can reduce the width of the outer frames of the display panel, thereby increasing the screen-to-body ratio of the display panel.

In one embodiment, a test terminal is formed from the conversion terminal layer, and a second opening is formed at a position on the first substrate corresponding to the test terminal. By forming the test terminal on the conversion terminal layer, connecting the test terminal to a display circuit, and forming the second opening on the first substrate, the test terminal can test the display circuit by the second opening when the display panel is manufactured. As a result, the circuits of the display panel can be ensured to work normally.

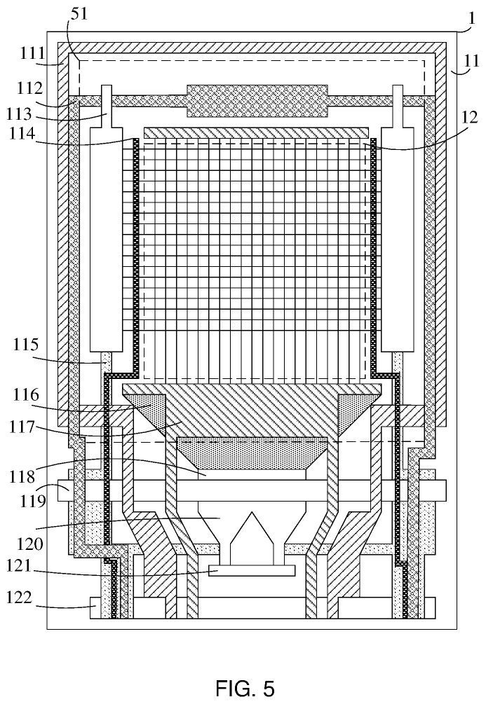

Compared with conventional display devices, the display device of the present disclosure is provided with a through-hole. In one embodiment, as shown in FIG. 5, a plurality of through-holes 51 are formed on a display device and are defined around the display device. Therefore, the through-holes exist at the outer frames of the display device. Correspondingly, lines, which are originally disposed at the outer frames of conventional display devices, are disposed on the conversion terminal layer without changing arrangements of lines and components in the display area. In addition, each line of the conversion terminal layer is connected to the driving circuit layer by the through-holes provided by the conversion terminal layer, thereby realizing functions of each circuit and each line. Furthermore, only the display area and the hole defining area around the display area exist, and the hole defining area has a relatively small size and will even be encapsulated in an actual product. Therefore, the screen-to-body ratio of the display panel can be increased, and a full-screen panel can even be realized. In conventional display panels, clock signal lines are disposed at outer frames at two sides of the display panels. In the present embodiment, the clock signal lines are formed from the conversion terminal layer, so that a width of the outer frames at two sides of the display panels can be reduced. Correspondingly, the electrostatic protection circuit, the power supply voltage line, and the test terminal are formed from the conversion terminal layer, thereby further reducing the width of the outer frames, or even omitting the outer frames. In the conventional display panels, the power supply voltage line is disposed at a top outer frame. In the present embodiment, the power supply voltage line is disposed on the conversion terminal layer, thereby omitting the top frame, and increasing the screen-to-body ratio of the display panel.

It should be noted that positions of the through-holes in FIG. 5 are demonstrated by a dotted line for the sake of clearness. In practical situations, a width of the through-holes is determined according to an actual size of the through-holes.

As seen from FIG. 4, compared with the conventional display panels, the width of the top outer frame of the display panel provided by the present embodiment is reduced because the power supply voltage line of the display panel is formed on a top side of the conversion terminal layer, a width of a bottom outer frame of the display panel provided by the present embodiment is reduced because the fan-out area and the driving circuit binding area are formed on a bottom side of the conversion terminal layer, and a width of the outer frames at two sides of the display panel provided by the present embodiment is reduced because the clock signal lines are disposed at a left side and a right side of the conversion terminal layer. As a result, the width of the outer frames around the display panel is reduced, and the screen-to-body of the display panel is increased. Of course, other lines can also be formed from the conversion terminal layer, which are not limited by the present embodiment. Furthermore, each line formed on the conversion terminal layer is based on a position of each line in the conventional display panels. For example, the clock signal lines are disposed at two sides of the conventional display panels; therefore, in the present embodiment, the clock signal lines may also be disposed at two sides of the conversion terminal layer, and extending directions and arrangements of lines in other areas of the display panels can remain unchanged. For instance, arrangements of lines in the display area can remain unchanged, so that the lines can be directly connected to the conversion terminal layer by through-holes to realize functions of the clock signal lines. As a result, in the present embodiment, changes in arrangements of lines of the display panel are slight, so that the lines in the display panel can be formed easily.

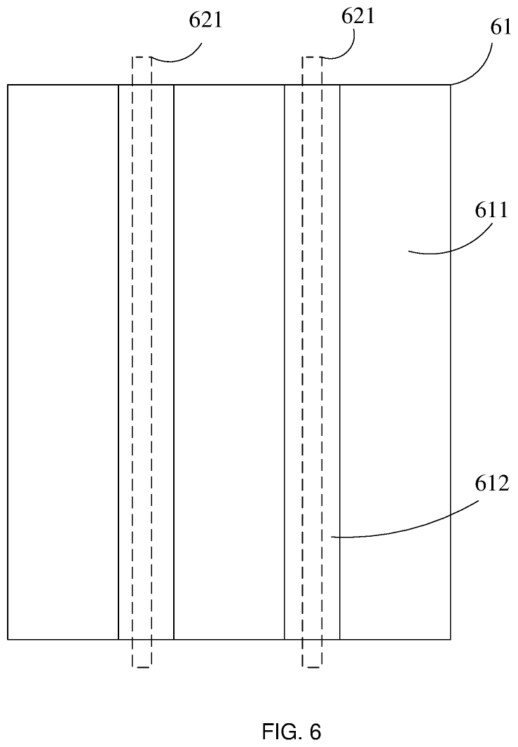

Specifically, as shown in FIG. 6, a circuit disposing area 61 at a right side of the conventional display panels includes a plurality of gate driving circuit disposing areas 611 and a plurality of clock signal line disposing areas 612 disposed between the gate driving circuit disposing areas 611. A plurality of transistors, a plurality of storage capacitors, and a plurality of connecting lines are disposed in the gate driving circuit disposing area 611, and a plurality of clock signal lines are disposed in the clock signal line disposing area. In the present embodiment, a plurality of through-holes 621 are defined in the clock signal line disposing areas 612, thereby allowing lines in the clock signal line disposing areas 612 and the gate driving circuit disposing areas 611 to be disposed on the conversion terminal layer. Furthermore, the transistors can be connected to each of the lines by the through-holes, so that the gate driving circuit can work normally. Correspondingly, a width of the circuit disposing area is reduced, and the screen-to-body ratio of the display panel is increased.

Considering that a material of each line formed from the terminal conversion layer by etching and a material of the source/drain layer of the conventional display panels are same, in the present embodiment, the material of the conversion terminal layer and the material of the source/drain layer are same. Therefore, properties of the lines formed from the conversion terminal layer remain unchanged, and each driving circuit and each driving line can work normally.

In one embodiment, a conductive material is disposed in the first through-hole. The data line of the source/drain layer is connected to the conductive material, and the terminal is connected to the conductive material. Therefore, the data line can be connected to the conversion terminal by the conductive material disposed in the first through-hole. As a result, the first metal layer is not directly connected to the conversion terminal, so that the data line does not need to cross the first barrier layer, the second substrate, the second barrier layer, the buffer layer, the active layer, the first gate insulating layer, the first metal layer, the second gate insulating layer, and the second metal layer. Thus, problems of the data line occurring in the first through-hole, such as breakage or poor connection, are prevented. Therefore, the data line and the conversion terminal can be well connected to each other, and corresponding functions thereof can be realized.

In one embodiment, a conductive material is disposed in the second through-hole. The gate is connected to the conductive material, and the clock signal lines are connected to the conductive material. Therefore, the gate can be connected to the clock signal lines by the conductive material disposed in the second through hole. As a result, the gate is not directly connected to the clock signal lines, so that it does not need to cross the first barrier layer, the second flexible layer, the second barrier layer, the buffer layer, the active layer, and the first gate insulating layer, and a crossing area can be reduced. In the present embodiment, problems of the gate occurring in the second through-hole, such as breakage or poor connection, are prevented due to the conductive material. Therefore, the gate and the clock signal lines can be well connected to each other, and corresponding functions thereof can be realized.

In one embodiment, the conductive material includes one of Ti, Al, or Cu.

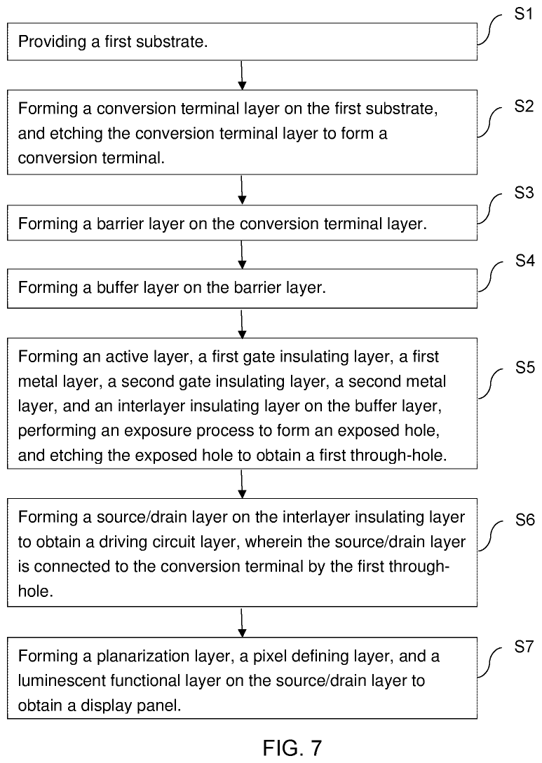

As shown in FIG. 7, an embodiment of the present disclosure provides a method of manufacturing a display panel, including following steps:

S1: providing a first substrate;

S2: forming a conversion terminal layer on the first substrate, and etching the conversion terminal layer to form a conversion terminal;

S3: forming a barrier layer on the conversion terminal layer;

S4: forming a buffer layer on the barrier layer;

S5: forming an active layer, a first gate insulating layer, a first metal layer, a second gate insulating layer, a second metal layer, and an interlayer insulating layer on the buffer layer, performing an exposure process to form an exposed hole, and etching the exposed hole to obtain a first through-hole;

S6: forming a source/drain layer on the interlayer insulating layer to obtain a driving circuit layer, wherein the source/drain layer is connected to the conversion terminal by the first through-hole; and

S7: forming a planarization layer, a pixel defining layer, and a luminescent functional layer on the source/drain layer to obtain the display panel.

The present embodiment provides the method of manufacturing the display panel. In the method, the conversion terminal layer is formed on the first substrate, and is etched to form the conversion terminal. After that, the barrier layer, the buffer layer, the active layer, the first gate insulating layer, the first metal layer, the second gate insulating layer, the second metal, and the interlayer insulating layer are formed on the conversion terminal layer. Then, the exposed hole is created by exposure, and is etched to obtain the first through-hole. Therefore, the source/drain layer can be connected to the conversion terminal by the first through-hole after being formed on the interlayer insulating layer. Then, the planarization layer, the pixel defining layer, and the luminescent functional layer are formed on the source/drain layer to obtain the display panel. The conversion terminal layer is formed on the first substrate of the display panel to form the conversion terminal. A first opening is formed at a position on the first substrate corresponding to the conversion terminal, so that a data line formed from the source/drain layer can be connected to the conversion terminal, and a driver chip can be connected to the data line of the source/drain layer by the conversion terminal layer. Therefore, the driver chip can be connected to the display panel without defining a fan-out area, a binding terminal, and a bending area at a bottom outer frame of the display panel, which reduces the width of outer frames and increases the screen-to-body ratio of the display panel. As a result, a following technical problem can be alleviated: widths of outer frames of conventional display devices are greater due to many lines disposed at the outer frames, resulting in relatively low screen-to-body ratio of the display devices.

In one embodiment, before the step of providing the first substrate, the method further includes: providing a substrate, and coating polyimide on the substrate to form the first substrate.

In one embodiment, before the step of forming the source/drain layer on the interlayer insulating layer, the method further includes: depositing a conductive material in the first through-hole, thereby connecting the data line of the source/drain layer to the conversion terminal by the conductive material.

In one embodiment, the active layer, the first gate insulating layer, the first metal layer, the second gate insulating layer, the second metal layer, and the interlayer insulating layer are formed on the buffer layer. The step of performing the exposure process to form the exposed hole, and etching the exposed hole to obtain the first through-hole includes: forming the first metal layer on the first gate insulating layer.

In one embodiment, before the step of forming the first metal layer on the first gate insulating layer, the method further includes: performing an exposure process to form an exposed hole, etching the exposed hole to obtain a second through-hole, and disposing a conductive material in the second through-hole.

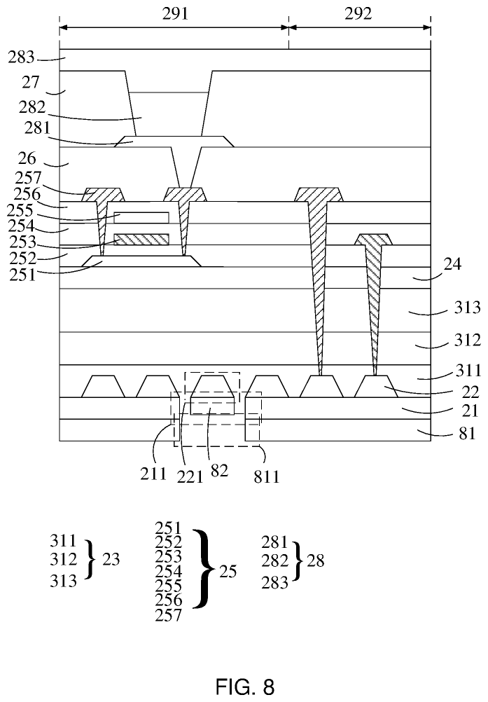

As shown in FIG. 8, an embodiment of the present disclosure provides a display device, including:

a display panel including a first substrate 21, a conversion terminal layer 22, a barrier layer 23, a buffer layer 24, a driving circuit layer 25, a planarization layer 26, a pixel defining layer 27, and a luminescent functional layer 28. The conversion terminal layer 22 is disposed on the first substrate 21 to form a conversion terminal 221. The barrier layer 23 is disposed on the conversion terminal layer 22. The buffer layer 24 is disposed on the barrier layer 23. The driving circuit layer 25 includes an active layer 251, a first gate insulating layer 252, a first metal layer 253, a second gate insulating layer 254, a second metal layer 255, an interlayer insulating layer 256, and a source/drain layer 257. The driving circuit layer 25 is disposed on the buffer layer 24. A first opening 211 is disposed at a position on the first substrate 21 corresponding to the conversion terminal 221, and a data line formed from the source/drain layer 257 is connected to the conversion terminal 221 by a first through-hole.

The display device further includes an auxiliary functional layer 81 disposed at a bottom side of the display panel; and

a driver chip 82 disposed at the bottom side of the display panel and connected to the conversion terminal 221.

The present embodiment provides the display device including the display panel, the auxiliary functional layer, and the driver chip. By forming the conversion terminal layer on the first substrate to form the conversion terminal and forming the first opening at the position on the first substrate corresponding to the conversion terminal, the driver chip can be connected to the data line of the source/drain layer by the conversion terminal layer. Therefore, the driver chip can be connected to the display panel without defining a fan-out area, a binding terminal, and a bending area at a bottom outer frame of the display panel, which reduces the width of the outer frames and increases the screen-to-body ratio of the display panel. As a result, a following technical problem can be alleviated: widths of outer frames of conventional display devices are greater due to many lines disposed at the outer frames, resulting in relatively low screen-to-body ratio of the display devices.

In one embodiment, as shown in FIG. 8, a third opening 811 is formed on the auxiliary functional layer 81. The driver chip 82 passes through the third opening 881 and to connect to the conversion terminal 221. When the driver chip is connected to the conversion terminal, the driver chip can be disposed at a bottom side of the auxiliary functional layer, and can be connected to the conversion terminal by the through-hole. Alternatively, as shown in FIG. 8, an opening is formed on the auxiliary functional layer and the first substrate, so that the driver chip is directly connected to the conversion terminal layer by the opening.

In one embodiment, the auxiliary functional layer includes a support layer, a heat dissipation layer, and a backplate. By disposing the auxiliary functional layer at the bottom side of the display panel and disposing the back plate and the support layer to support the display panel, flatness of the display panel can be ensured. Moreover, the heat dissipation layer is used to dissipate heat from the driver chip and the display panel, thereby preventing overly-high temperature of the driver chip, and protecting the driver chip.

In one embodiment, in the display device, a fan-out line is formed from the conversion terminal layer, an end of the fan-out line is connected to the conversion terminal, and another end of the fan-out line is connected to the data line of the source/drain layer by the first through-hole.

In one embodiment, in the display device, a clock signal line is formed from the conversion terminal layer, an end of the clock signal line is connected to the conversion terminal, and another end of the clock signal line is connected to a gate driving circuit of the display panel.

In one embodiment, in the display device, the first metal layer is etched to form a gate, and the clock signal line is connected to the gate by a second through-hole.

In one embodiment, in the display device, an electrostatic protection circuit line is formed from the conversion terminal layer, an end of the electrostatic protection circuit line is connected to the conversion terminal, and another end of the electrostatic protection circuit line is connected to an electrostatic protection circuit of the display panel.

In one embodiment, in the display device, a test terminal is formed from the conversion terminal layer, and a second opening is formed at a position on the first substrate corresponding to the test terminal.

In one embodiment, in the display device, the barrier layer includes a first barrier layer, a second barrier layer, and a second substrate disposed between the first barrier layer and the second barrier layer, the first barrier layer is disposed on the first substrate, and the conversion terminal layer includes a first part disposed on the first substrate and a second part disposed on the second substrate.

In one embodiment, a material of the conversion terminal layer and a material of the conversion terminal layer are the same.

In one embodiment, the material of the conversion terminal layer includes at least one of Ti, Al, or Cu.

According to the above embodiments:

a display panel, a manufacturing method thereof, and a display device are provided. The display panel includes a first substrate, a conversion terminal layer, a barrier layer, a buffer layer, a driving circuit layer, a planarization layer, a pixel defining layer, and a luminescent functional layer. The conversion terminal layer is disposed on the first substrate to form a conversion terminal. The barrier layer is disposed on the conversion terminal layer. The buffer layer is disposed on the barrier layer. The driving circuit layer includes an active layer, a first gate insulating layer, a first metal layer, a second gate insulating layer, a second metal layer, an interlayer insulating layer, and a source/drain layer. The driving circuit layer is disposed on the buffer layer. Wherein, a first opening is formed at a position on the first substrate corresponding to the conversion terminal, and a data line formed from the source/drain layer is connected to the conversion terminal by a first through-hole. In the present disclosure. By forming the conversion terminal layer on the first substrate to form the conversion terminal and forming the first opening at the position on the first substrate corresponding to the conversion terminal, the data line formed from the source/drain layer can be connected to the conversion terminal by the first through-hole, and a driver chip can be connected to the data line of the source/drain layer by the conversion terminal layer. Therefore, the driver chip can be connected to the display panel without defining a fan-out area, a binding terminal, and a bending area at a bottom outer frame of the display panel, which reduces a width of the outer frames and increases a screen-to-body ratio of the display panel. As a result, a following technical problem can be alleviated: widths of outer frames of conventional display devices are greater due to many lines disposed at the outer frames, resulting in relatively low screen-to-body ratio of the display devices.

In summary, many changes and modifications to the described embodiments can be carried out by those skilled in the art, and all such changes and modifications are intended to be included within the scope of the appended claims.

What is claimed is:

1. A display panel, comprising:
a first substrate;
a conversion terminal layer disposed on the first substrate to form a conversion terminal;
a barrier layer disposed on the conversion terminal layer;
a buffer layer disposed on the barrier layer;
a driving circuit layer comprising an active layer, a first gate insulating layer, a first metal layer, a second gate insulating layer, a second metal layer, an interlayer insulating layer, and a source/drain layer, wherein the driving circuit layer is disposed on the buffer layer;
a planarization layer;
a pixel defining layer; and
a luminescent functional layer;
wherein a first opening is formed at a position on the first substrate corresponding to the conversion terminal, and a data line formed from the source/drain layer is connected to the conversion terminal by a first through-hole.

2. The display panel of claim 1, wherein a fan-out line is formed from the conversion terminal layer, an end of the fan-out line is connected to the conversion terminal, and another end of the fan-out line is connected to the data line of the source/drain layer by the first through-hole.

3. The display panel of claim 1, wherein a clock signal line is formed from the conversion terminal layer, an end of the clock signal line is connected to the conversion terminal, and another end of the clock signal line is connected to a gate driving circuit of the display panel.

4. The display panel of claim 3, wherein the first metal layer is etched to form a gate, and the clock signal line is connected to the gate by a second through-hole.

5. The display panel of claim 1, wherein an electrostatic protection circuit line is formed from the conversion terminal layer, an end of the electrostatic protection circuit line is connected to the conversion terminal, and another end of the electrostatic protection circuit line is connected to an electrostatic protection circuit of the display panel.

6. The display panel of claim 1, wherein a test terminal is formed from the conversion terminal layer, and a second opening is formed at a position on the first substrate corresponding to the test terminal.

7. The display panel of claim 1, wherein the barrier layer comprises a first barrier layer, a second barrier layer, and a second substrate disposed between the first barrier layer and the second barrier layer, the first barrier layer is disposed on the first substrate, and the conversion terminal layer comprises a first part disposed on the first substrate and a second part disposed on the second substrate.

8. The display panel of claim 1, wherein a material of the conversion terminal layer and a material of the source/drain layer are same.

9. A method of manufacturing a display panel, comprising following steps:
providing a first substrate;
forming a conversion terminal layer on the first substrate, and etching the conversion terminal layer to form a conversion terminal;
forming a barrier layer on the conversion terminal layer;
forming a buffer layer on the barrier layer;
forming an active layer, a first gate insulating layer, a first metal layer, a second gate insulating layer, a second metal layer, and an interlayer insulating layer on the buffer layer, performing an exposure process to form an exposed hole, and etching the exposed hole to obtain a first through-hole;
forming a source/drain layer on the interlayer insulating layer to obtain a driving circuit layer, wherein the source/drain layer is connected to the conversion terminal by the first through-hole; and
forming a planarization layer, a pixel defining layer, and a luminescent functional layer on the source/drain layer to obtain the display panel.

10. A display device, comprising:
a display panel comprising a first substrate, a conversion terminal layer, a barrier layer, a buffer layer, a driving circuit layer, a planarization layer, a pixel defining layer, a luminescent functional layer, wherein the conversion terminal layer is disposed on the first substrate to form a conversion terminal, the barrier layer is disposed on the conversion terminal layer, the buffer layer is disposed on the barrier layer, the driving circuit layer comprises an active layer, a first gate insulating layer, a first metal layer, a second gate insulating layer, a second metal layer, an interlayer insulating layer, and a source/drain layer, and the driving circuit layer is disposed on the buffer layer, and wherein a first opening is formed at a position on the first substrate corresponding to the conversion terminal, and a data line formed from the source/drain layer is connected to the conversion terminal by a first through-hole; and
the display device further comprises:
an auxiliary functional layer disposed at a bottom side of the display panel; and
a driver chip disposed at the bottom side of the display panel and connected to the conversion terminal.

11. The display device of claim 10, wherein a third opening is formed on the auxiliary functional layer, and the driver chip is connected to the conversion terminal by the third opening.

12. The display device of claim 10, wherein the auxiliary functional layer comprises a support layer, a heat dissipation layer, and a backplate.

13. The display device of claim 10, wherein a fan-out line is formed from the conversion terminal layer, an end of the fan-out line is connected to the conversion terminal, and another end of the fan-out line is connected to the data line of the source/drain layer by the first through-hole.

14. The display device of claim 10, wherein a clock signal line is formed from the conversion terminal layer, an end of the clock signal line is connected to the conversion terminal, and another end of the clock signal line is connected to a gate driving circuit of the display panel.

15. The display device of claim 14, wherein the first metal layer is etched to form a gate, and the clock signal line is connected to the gate by a second through-hole.

16. The display device of claim 10, wherein an electrostatic protection circuit line is formed from the conversion terminal layer, an end of the electrostatic protection circuit line is connected to the conversion terminal, and another end of the electrostatic protection circuit line is connected to an electrostatic protection circuit of the display panel.

17. The display device of claim 10, wherein a test terminal is formed from the conversion terminal layer, and a second opening is formed at a position on the first substrate corresponding to the test terminal.

18. The display device of claim 10, wherein the barrier layer comprises a first barrier layer, a second barrier layer, and a second substrate disposed between the first barrier layer and the second barrier layer, the first barrier layer is disposed on the first substrate, and the conversion terminal layer comprises a first part disposed on the first substrate and a second part disposed on the second substrate.

19. The display device of claim 10, wherein a material of the conversion terminal layer and a material of the source/drain layer are same.

20. The display device of claim 19, wherein the material of the conversion terminal layer comprises at least one of Ti, Al, or Cu.
